(19) United States
(12) Patent Application Publication
(10) Pub. No.: US 2011/0228893 A1
(43) Pub. Date: Sep. 22, 2011

(54) SHIFT REGISTER CIRCUIT

(75) Inventors: Youichi TOBITA, Tokyo (JP); Hiroyuki Murai, Tokyo (JP)

(73) Assignee: MITSUBISHI ELECTRIC CORPORATION, Chiyoda-ku (JP)

(21) Appl. No.: 13/030,578

(22) Filed: Feb. 18, 2011

(30) Foreign Application Priority Data
Mar. 18, 2010 (JP) 2010-062291

(51) Int. Cl. G11C 19/00

(52) U.S. Cl. 377/77

(57) ABSTRACT

A shift register circuit includes a first transistor which supplies a clock signal to an output terminal, and an inverter which drives a second transistor for discharging a gate of the first transistor. An input node of the inverter is separated from the gate of the first transistor, and the gates of the first and second transistors are charged and discharged by separate circuits, respectively.

### BACKGROUND OF THE INVENTION

1. Field of the Invention

The present invention relates to a scanning-line drive circuit, and particularly to a shift register circuit which is applicable to a scanning-line drive circuit configured with only field effect transistors of the same conductivity type and which is used in an electro-optical device such as an image display device and an image sensor.

2. Description of the Background Art

An electro-optical device including a scanning-line drive circuit connected to a scanning line and scanning pixels is widely known. For example, in an image display device (hereinafter, referred to as a “display device”) such as a liquid crystal display device, a gate line (scanning line) is provided for each of pixel lines of a display element (display panel) having a plurality of pixels arranged in lines and columns (in a matrix), and the gate lines are sequentially selected and driven in the cycle of one horizontal period of a display signal, to thereby update a display image. As a gate-line drive circuit (scanning-line drive circuit) for sequentially selecting and driving the pixel lines, that is, the gate lines, there may be adopted a shift register which performs shifting whose one-round operation is made in a one-frame period of the display signal.

Pixels of an imaging element used in an imaging device are also arranged in a matrix, and these pixels are scanned by a gate-line drive circuit to thereby extract data of a captured image. A shift register may be adopted as a gate-line drive circuit of the imaging device, too.

A shift register adopted as the gate-line drive circuit is desirably configured with only field effect transistors of the same conductivity type, in order to reduce the number of steps included in a display device manufacturing process. Therefore, a variety of shift registers configured with only N-type or P-type field effect transistors, and a variety of display devices equipped with the shift registers have been proposed (for example, Japanese Patent Application Publication No. 2004-246358; Japanese Patent Application Publication No. 2004-103226; Japanese Patent Application Publication No. 2007-179660; and Japanese Patent Application Publication No. 2007-207411).

In a shift register serving as a gate-line drive circuit, a plurality of shift register circuits each provided for each pixel line, that is, for each gate line, are cascade-connected with one another. In this specification, for convenience of the description, each of the plurality of shift register circuits included in the gate-line drive circuit is called a “unit shift register”. Thus, an output terminal of each individual unit shift register included in the gate-line drive circuit is connected to an input terminal of a next-stage or subsequent-stage unit shift register.

For example, a unit shift register as represented in FIG. 1 of Japanese Patent Application Publication No. 2004-246358 includes, at an output stage thereof, a first transistor (pull-up MOS transistor Q1 of Japanese Patent Application Publication No. 2004-246358) and a second transistor (pull-down MOS transistor Q2). The first transistor is connected between an output terminal (the first gate voltage signal terminal GOUT) and a clock terminal (first power clock CKV). The second transistor is connected between the output terminal and a reference voltage terminal (gate-off voltage terminal VOFF). An output signal of the unit shift register is outputted by a clock signal inputted to the clock terminal being transferred to the output terminal in a state where the first transistor is ON and the second transistor is OFF.

Particularly, in each of the unit shift registers included in the gate-line drive circuit, a high drive capability (capability of flowing a current) is required of the first transistor, because it is necessary to charge the gate line at a high speed by using the output signal thereof. Accordingly, it is desirable that even while the source of the output terminal which is the first transistor is at the high (H) level, the voltage between the gate and the source of the first transistor is kept high. Therefore, in the unit shift register disclosed in Japanese Patent Application Publication No. 2004-246358, a boost capacitance (capacitance element C) is provided between the gate and the source of the first transistor, so that when the output terminal is brought into the H level, the gate of the first transistor is also boosted.

As the degree of the boosting is larger, the voltage between the gate and the source of the first transistor increases, and therefore the drive capability of the first transistor can be increased. In other words, it is necessary to boost the gate of the first transistor more largely, in order that the unit shift register can charge the gate line at a high speed.

### SUMMARY OF THE INVENTION

An object of the present invention is to improve a drive capability of a shift register circuit and to increase an operation speed.

A shift register circuit according to the present invention includes an input terminal, an output terminal, a reset terminal, and a clock terminal, and also includes first and second transistors, an inverter, first and second charge circuits, and first and second discharge circuits which will be described as follows. The first transistor supplies a clock signal inputted to the clock terminal, to the output terminal. The second transistor discharges a first node to which a control electrode of the first transistor is connected. An output end of the inverter is a second node to which a control electrode of the second transistor is connected. The first charge circuit charges the first node in accordance with activation of an input signal inputted to the input terminal. The first discharge circuit discharges the first node in accordance with activation of a reset signal inputted to the reset terminal. The second charge circuit charges a third node which is an input end of the inverter, in accordance with activation of the input signal. The second discharge circuit discharges the third node in accordance with activation of the reset signal.

Since the control electrode (first node) of the first transistor and the input end (third node) of the inverter are separated from each other, a parasitic capacitance of the first node can be reduced. Accordingly, a boost amount of the first node at a time when the output signal is activated is increased, to consequently obtain a high drive capability in the first transistor. Therefore, this unit shift register can charge a gate line at a high speed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram schematically showing a configuration of a liquid crystal display device;

FIG. 2 shows an exemplary configuration of a gate-line drive circuit according to a preferred embodiment of the present invention;

FIG. 3 is a circuit diagram of a conventional unit shift register;

FIG. 4 is a timing chart showing an operation of the gate-line drive circuit of FIG. 2;

FIG. 5 shows another exemplary configuration of the gate-line drive circuit according to the preferred embodiment of the present invention;

FIG. 6 is a timing chart showing an operation of the gate-line drive circuit of FIG. 5;

FIG. 7 is a circuit diagram of a unit shift register according to the preferred embodiment of the present invention;

FIG. 8 is a circuit diagram of a unit shift register according to a first modification of the preferred embodiment;

FIG. 9 is a circuit diagram of a unit shift register according to a second modification of the preferred embodiment;

FIG. 10 is a circuit diagram of a unit shift register according to a third modification of the preferred embodiment;

FIG. 11 is a circuit diagram of a unit shift register according to a fourth modification of the preferred embodiment;

FIG. 12 is a circuit diagram of a unit shift register according to a fifth modification of the preferred embodiment; and

FIG. 13 is a circuit diagram of a unit shift register according to a sixth modification of the preferred embodiment.

### DESCRIPTION OF THE PREFERRED EMBODIMENTS

Hereinafter, a preferred embodiment of the present invention will be described with reference to the accompanying drawings. In order to avoid duplicative and thus redundant descriptions, elements having the same or equivalent function are denoted by the same reference sign in the drawings.

A transistor used in each preferred embodiment is an insulated gate type field effect transistor. In the insulated gate type field effect transistor, the electrical conductivity between a drain region and a source region in the semiconductor layer is controlled by an electric field in a gate insulating film. As a material of the semiconductor layer in which the drain region and the source region are formed, an organic semiconductor of polysilicon, amorphous silicon, pentacene or the like, or an oxide semiconductor of single-crystal silicon, IGZO(In—Ga—Zn—O) or the like, can be adopted, for example.

As well known, a transistor is an element having at least three electrodes including a control electrode (a gate (electrode) in a limited sense), one current electrode (a drain (electrode) or a source (electrode) in a limited sense), and the other current electrode (a source (electrode) or a drain (electrode) in a limited sense). The transistor functions as a switching element in which a channel is formed between a drain and a source by application of a predetermined voltage to a gate. The drain and the source of the transistor basically have identical structures, and their nominal designations are exchanged depending on the conditions of a voltage applied. For example, in an N-type transistor, an electrode having a relatively high potential (hereinafter also referred to as a “level”) is called a drain while an electrode having relatively low potential is called a source (in a P-type transistor, the reverse applies).

If not otherwise specified, the transistor may be formed on a semiconductor substrate, or may be a thin-film transistor (TFT) formed on an insulating substrate of glass or the like. As a substrate on which the transistor is formed, there may be adopted a single-crystal substrate, or an insulating substrate of SOI, glass, a resin, or the like.

A gate-line drive circuit of the present invention is formed using only transistors of a single conductivity type. For example, an N-type transistor is activated (an ON state, a conducting state) when the voltage between the gate and the source thereof is at the H (high) level which is higher than a threshold voltage of this transistor, and deactivated (an OFF state, a non-conducting state) when the voltage is at the L (low) level which is lower than the threshold voltage. Accordingly, in a circuit using an N-type transistor, the H level of a signal corresponds to an “activation level”, and the L level thereof corresponds to a “deactivation level”. In the circuit using the N-type transistor, when each node is charged and brought into the H level, a shift from the deactivation level to the activation level occurs, and when the node is discharged and brought into the L level, a shift from the activation level to the deactivation level occurs.

On the other hand, a P-type transistor is activated (an ON state, a conducting state) when the voltage between the gate and the source thereof is at the L level which is lower than a threshold voltage (a negative value based on the source) of the transistor, and deactivated (an OFF state, a non-conducting state) when the voltage is at the H level which is higher than the threshold voltage. Accordingly, in a circuit using a P-type transistor, the L level of a signal corresponds to an “activation level”, and the H level thereof corresponds to a “deactivation level”. In the circuit using the P-type transistor, the relationship of charging and discharging of each node is opposite to that of the N-type transistor. Thus, when each node is charged and brought into the L level, a shift from the deactivation level to the activation level occurs, and when the node is discharged and brought into the H level, a shift from the activation level to the deactivation level occurs.

In this specification, the shift from the deactivation level to the activation level is defined as a “pull-up”, and the shift from the activation level to the deactivation level is defined as “pull-down”. That is, in the circuit using the N-type transistor, the shift from the L level to the H level is defined as “pull-up” and the shift from the H level to the L level is defined as “pull-down”, whereas in the circuit using the P-type transistor, the shift from the H level to the L level is defined as “pull-up” and the shift from the L level to the H level is defined as “pull-down”.

Moreover, in this specification, a description is based on the assumption that “connection” between two elements, between two nodes, or between one element and one node includes a state equivalent to substantially direct connection, though the connection is made through another component (such as an element or a switch). For example, even in a case where two elements are connected via a switch, the relationship between the two elements is described as “connection” if they can function in the same manner as when they are directly connected to each other.

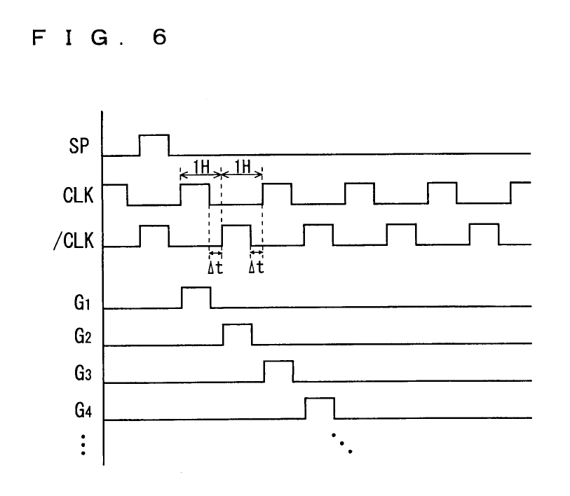

In the present invention, clock signals (multi-phase clock signals) having different phases are used. In the following, for easy description, a certain interval is provided between an activation period of one clock signal and an activation period of a clock signal which is activated next to the one clock signal (Δt in FIGS. 4 and 6). However, in the present invention, it suffices that the activation periods of the respective clock signals do substantially not overlap one another, and thus the interval may not necessarily be provided. For example, when the H level corresponds to the activation level, a fall timing (a shift from the H level to the L level) of one clock signal may be concurrent with a rise timing (a shift from the L level to the H level).

### Preferred Embodiment 1

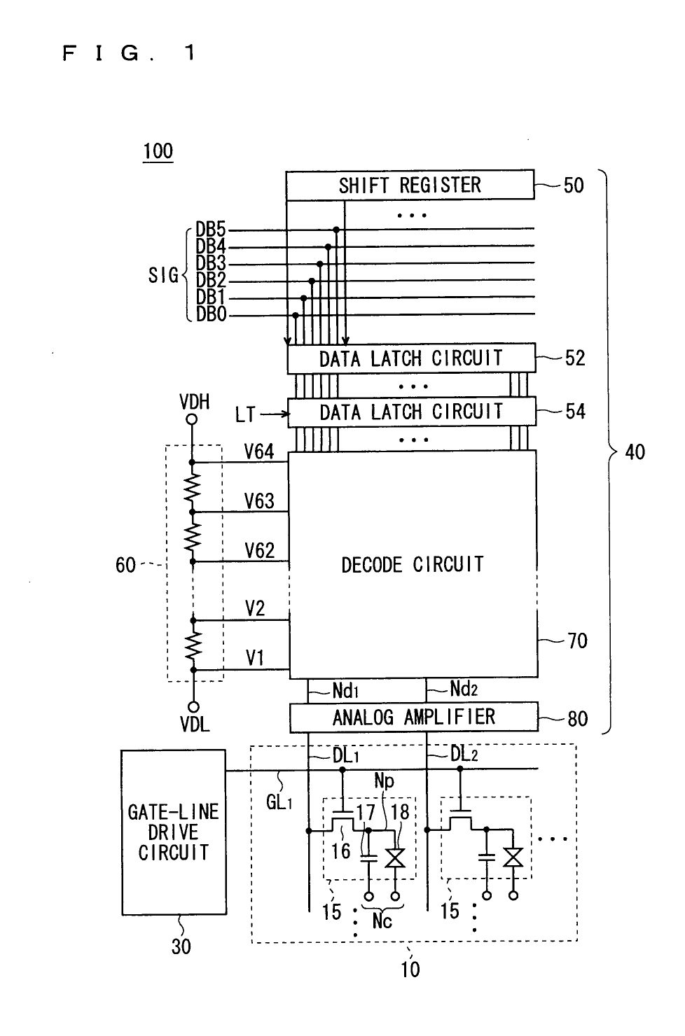

FIG. 1 is a block diagram schematically showing a configuration of a display device according to the present invention. FIG. 1 shows an overall configuration of a liquid crystal display device as a typical example of the display device. Application of the present invention is not limited to the liquid crystal display device, and the present invention can be widely applied to electro-optical devices including a display device which converts an electrical signal into a light brightness, as exemplified by an electro-luminescence (EL), an organic EL, a plasma display, and an electronic paper, and an imaging device (image sensor) which converts a light intensity into an electrical signal.

A liquid crystal display device 100 includes a liquid crystal array section 10, a gate-line drive circuit (scanning-line drive circuit) 30, and a source driver 40. A shift register according to this preferred embodiment is mounted in the gate-line drive circuit 30, which will be clearly described later.

The liquid crystal array section 10 includes a plurality of pixels 15 arranged in lines and columns. Gate lines GL₁, GL₂ . . . (collectively called “gate lines GL”) are arranged in the respective lines of pixels (hereinafter also referred to as “pixel lines”). Data lines DL₁, DL₂ . . . (collectively called “data lines DL”) are arranged in the respective columns of pixels (hereinafter also referred to as “pixel columns”). In FIG. 1, the pixel 15 in the first line and the first column, the pixel 15 in the first line and the second column, and the gate line GL₁ and the data lines DL₁, DL₂ corresponding to these pixels 15 are shown as a representative.

Each pixel 15 has a pixel switching element 16 provided between the corresponding data line DL and a pixel node Np, and a capacitor 17 and a liquid crystal display element 18 connected in parallel with each other between the pixel node Np and a common electrode node Nc. The liquid crystal orientation in the liquid crystal display element 18 changes depending on a voltage difference between the pixel node Np and the common electrode node Nc. In response to this change, the display brightness of the liquid crystal display element 18 changes. Thereby, the brightness of each pixel can be controlled by a display voltage transmitted to the pixel node Np via the data line DL and the pixel switching element 16. That is, an intermediate voltage difference located between the voltage difference corresponding to the maximum brightness and the voltage difference corresponding to the minimum brightness is applied to between the pixel node Np and the common electrode node Nc, thereby obtaining an intermediate brightness. Accordingly, gradational brightnesses can be obtained by setting the display voltage in stages.

The gate-line drive circuit 30 sequentially selects and activates the gate lines GL, based on a predetermined scanning cycle. A gate electrode of the pixel switching element 16 is connected to the corresponding gate line GL. While a particular gate line GL is selected, the pixel switching element 16 of each of the pixels connected to this gate line GL is in the conducting state, so that the pixel node Np is connected to the corresponding data line DL. Thus, the display voltage transmitted to the pixel node Np is held by the capacitor 17. In general, the pixel switching element 16 is configured as a TFT formed on the same insulation substrate (such as a glass substrate and a resin substrate) as the liquid crystal display element 18 is formed on.

The source driver 40 serves to output the display voltage to the data line DL. The display voltage is set in stages by a display signal SIG which is an N-bit digital signal. Here, in an example, it is assumed that the display signal SIG is a 6-bit signal, and includes display signal bits DB0 to DB5. Based on the 6-bit display signal SIG, a gradation display in 2⁶=64 stages is allowed in each pixel. Moreover, if one color display unit is formed with three pixels of R (Red), G (Green), and B (Blue), about 260,000 colors can be displayed.

As shown in FIG. 1, the source driver 40 includes a shift register 50, a data latch circuits 52, 54, a gradation voltage generation circuit 60, a decode circuit 70, and an analog amplifier 80.

In the display signal SIG, the display signal bits DB0 to DB5 corresponding to the display brightness of each pixel 15 are serially generated. That is, the display signal bits DB0 to DB5 at each timing indicate the display brightness of any one of the pixels 15 in the liquid crystal array section 10.

The shift register 50 instructs the data latch circuit 52 to load the display signal bits DB0 to DB5 at a timing synchronized with a cycle of switching the setting of the display signal SIG. The data latch circuit 52 sequentially loads the display signals SIG which are serially generated, and holds the display signals SIG for one pixel line.

A latch signal LT inputted to the data latch circuit 54 is activated at a timing when the display signals SIG for one pixel line are loaded in the data latch circuit 52. In response thereto, the data latch circuit 54 loads the display signals SIG for one pixel line which are held in the data latch circuit 52.

The gradation voltage generation circuit 60 includes sixty-three voltage dividing resistors connected in series with one another between a high voltage VDH and a low voltage VDL. The gradation voltage generation circuit 60 generates 64-stage gradation voltages V1 to V64.

The decode circuit 70 decodes the display signal SIG held in the data latch circuit 54, and based on a result of the decoding, selects a voltage from the gradation voltages V1 to V64 and outputs the selected voltage to each of decode output nodes Nd₁, Nd₂ . . . (collectively called “decode output nodes Nd”).

As a result, a display voltage (one of the gradation voltages V1 to V64) corresponding to each of the display signals SIG for one pixel line held in the data latch circuit 54 are outputted to the decode output nodes Nd simultaneously (in parallel). In FIG. 1, the decode output nodes Nd₁, Nd₂ corresponding to the data lines DL₁, DL₂ of the first and second columns are shown as a representative.

The analog amplifier 80 amplifies a current of an analog voltage corresponding to the display voltage outputted from the decode circuit 70 to each of the decode output nodes Nd₁, Nd₂ . . . and outputs it to each of the data lines DL₁, DL₂ . . . .

Based on the predetermined scanning cycle, the source driver 40 repeatedly outputs, to the data lines DL, the display voltages corresponding to a series of display signals SIG on one-pixel-line basis. The gate-line drive circuit 30 sequentially drives the gate lines GL₁, GL₂ . . . in synchronization with the scanning cycle. Thereby, an image display based on the display signals SIG is made in the liquid crystal array section 10.

Although in the liquid crystal display device 100 illustrated in FIG. 1, the gate-line drive circuit 30 and the source driver 40 are integrally configured with the liquid crystal array section 10, it may also be acceptable that the gate-line drive circuit 30 and the liquid crystal array section 10 are integrally configured while the source driver 40 is provided as an external circuit of the liquid crystal array section 10, or that the gate-line drive circuit 30 and the source driver 40 are provided as external circuits of the liquid crystal array section 10.

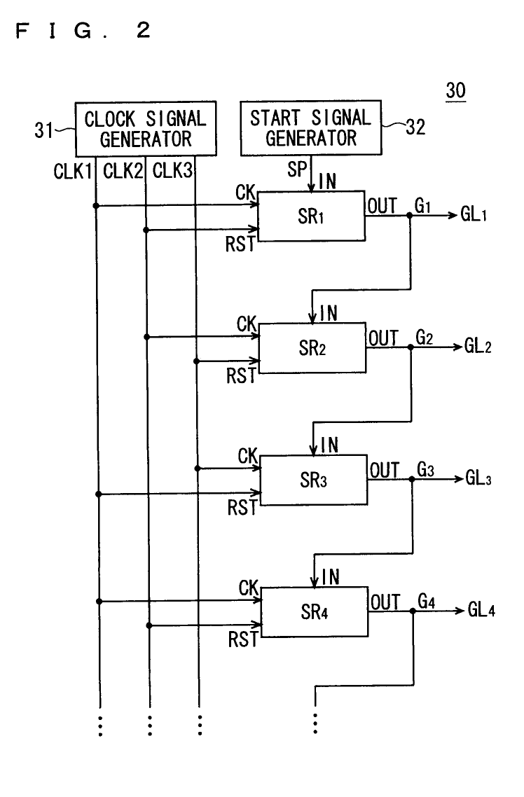

FIG. 2 shows a configuration of the gate-line drive circuit 30. The gate-line drive circuit 30 is configured as a shift register including a plurality of unit shift registers SR_{I}, SR₂, SR₃, SR₄ . . . which are cascade-connected with one another (for convenience of the description, the cascade-connected shift register circuits SR₁, SR₂ . . . are collectively referred to as “unit shift registers SR”). Each of the unit shift registers SR is provided for one pixel line, that is, for one gate line GL.

A clock signal generator 31 shown in FIG. 2 inputs three-phase clock signals CLK1, CLK2, CLK3 having different phases (having their activation periods not overlapping one another), to the unit shift registers SR of the gate-line drive circuit 30. The clock signals CLK1, CLK2, CLK3 are controlled by the clock signal generator 31 so as to be repeatedly and sequentially (that is, in the order of CLK1, CLK2, CLK3, CLK1 . . . ) activated at timings synchronized with the scanning cycle of the display device (FIG. 4).

Each of the unit shift registers SR has an input terminal IN, an output terminal OUT, a clock terminal CK, and a reset terminal RST. As shown in FIG. 2, any of the clock signals CLK1 to CLK3 is supplied to the clock terminal CK and the reset terminal RST of the unit shift register SR. Here, the clock signal which will be activated next to the clock signal inputted to the clock terminal CK is supplied to the reset terminal RST.

The gate line GL is connected to the output terminal OUT of each unit shift register SR. Thus, an output signal G of each unit shift register SR is, as a vertical (or horizontal) scanning pulse, outputted to the gate line GL.

A start pulse SP corresponding to the head of each frame period of an image signal is inputted as an input signal to the input terminal IN of the first-stage unit shift register SR₁. Input signals inputted to the input terminals IN of the unit shift registers SR of the second and subsequent stages are the output signals G outputted from the output terminals OUT of the unit shift registers SR of the immediately preceding stages.

In synchronization with the clock signals CLK1 to CLK3, each unit shift register SR of the gate-line drive circuit 30 time-shifts the signal (the start pulse SP or the output signal outputted from the immediately preceding stage) inputted to its input terminal IN, and transmits the resultant signal to the corresponding gate line GL and the next-stage unit shift register SR. Consequently, as shown in FIG. 4, the output signals G of the respective unit shift registers SR are sequentially activated in the order of G₁, G₂, G₃ . . . (details of the operation of the unit shift register SR will be described later). Thus, a series of the unit shift registers SR functions as a so-called gate line drive unit which sequentially activates the gate lines GL at timings based on the predetermined scanning cycle.

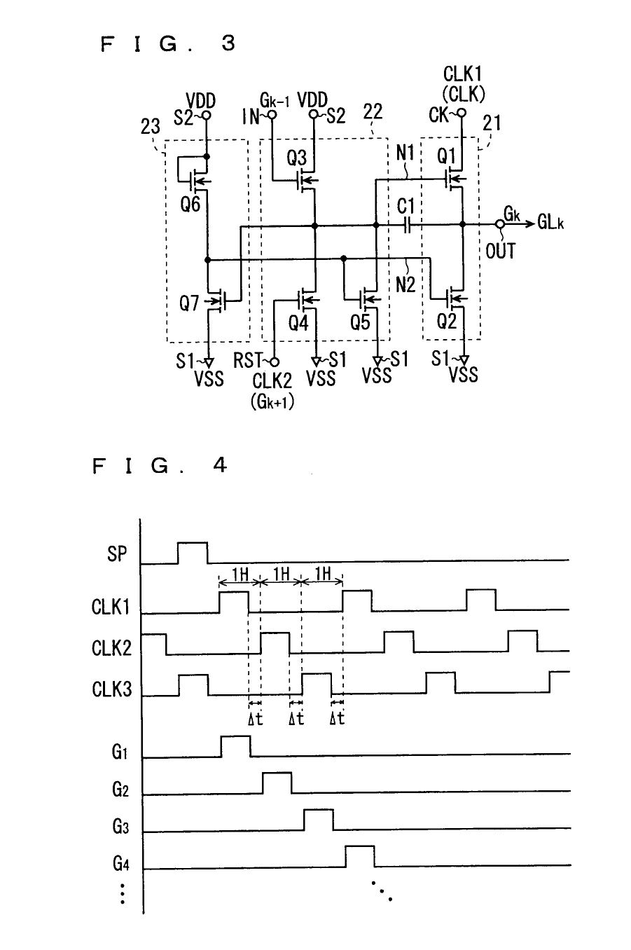

Here, for the purpose of facilitating the description of the present invention, a conventional unit shift register will be described. FIG. 3 is a circuit diagram showing a configuration of a conventional unit shift register SR. In the gate-line drive circuit 30, the cascade-connected unit shift registers SR have substantially identical configurations. Therefore, here, a configuration of the k-th unit shift register SRₖ will be described as a representative. All transistors included in the unit shift registers SR are field effect transistors of the same conductivity type, and N-type TFTs are used here.

As shown in FIG. 3, the conventional unit shift register SRₖ has not only the input terminal IN, the output terminal OUT, the clock terminal CK, and the reset terminal RST which are shown in FIG. 2, but also a first power supply terminal S1 and a second power supply terminal S2 to which a low-potential-side power supply potential (low-side power supply potential) VSS and a high-potential-side power supply potential (high-side power supply potential) VDD are supplied, respectively. In the following description, the low-side power supply potential VSS serves as a reference potential of the circuit (VSS=0), but in an actual use, the reference potential is set based on the voltage of data written into a pixel. For example, the high-side power supply potential VDD is set to 17V, and the low-side power supply potential VSS is set to −12V.

An output circuit 21 of the unit shift register SRₖ includes a transistor Q1 (output pull-up transistor) which activates (into the H level) the output signal Gₖ while the gate line GLk is selected, and a transistor Q2 (output pull-down transistor) which keeps the output signal Gₖ deactivated (in the L level) while the gate line GLk is not selected.

The transistor Q1 is connected between the output terminal OUT and the clock terminal CK, and activates the output signal Gₖ by supplying the clock signal inputted to the clock terminal CK, to the output terminal OUT. The transistor Q2 is connected between the output terminal OUT and the first power supply terminal S1, and keeps the output signal Gₖ at the deactivation level by discharging the output terminal OUT into the potential VSS. Here, a node connected to the gate (control electrode) of the transistor Q1 is defined as a “node N1”, and a node connected to the gate of the transistor Q2 is defined as a “node N2”.

A capacitance element C1 (boost capacitance) is provided between the gate and the source of the transistor Q1 (that is, between the output terminal OUT and the node N1). This capacitor element C1 capacitively couples the output terminal OUT with the node N1 to enhance a boost effect of the node N1 which is involved in the rise in level of the output terminal OUT.

A transistor Q3 is connected between the node N1 and the second power supply terminal S2, and the gate of the transistor Q3 is connected to the input terminal IN. The transistor Q3 functions so as to charge the node N1 in accordance with the activation of a signal (input signal) supplied to the input terminal IN.

A transistor Q4 having its gate connected to the reset terminal RST is connected between the node N1 and the first power supply terminal S1. The transistor Q4 functions so as to discharge the node N1 in accordance with the activation of a signal (reset signal) supplied to the reset terminal RST. A transistor Q5 having its gate connected to the node N2 is also connected between the node N1 and the first power supply terminal S1. The transistor Q5 functions so as to discharge the node N1 to keep the node N1 at the deactivation level (L level) while the node N2 is at the activation level (H level).

A circuit including these transistors Q3, Q4, Q5 forms a pull-up drive circuit 22 which drives the transistor Q1 (output pull-up transistor) by charging and discharging the node N1.

A transistor Q6 having its gate connected to the second power supply terminal S2 is connected between the node N2 and the second power supply terminal S2 (that is, the transistor Q6 is diode-connected). A transistor Q7 having its gate connected to the node N1 is connected between the node N2 and the first power supply terminal S1.

The transistor Q7 is set such that its on-resistance can be sufficiently small (that is, its drive capability can be high) as compared with the transistor Q6. Therefore, when the gate (node N1) of the transistor Q7 is brought into the H level so that the transistor Q7 is turned on, the node N2 is discharged to the L level, whereas when the node N1 is brought into the L level so that the transistor Q7 is turned off, the node N2 is brought into the H level. That is, the transistors Q6, Q7 form a ratio-type inverter whose input and output ends are the nodes N1 and N2, respectively. In this inverter, the transistor Q6 functions as a load element, and the transistor Q7 functions as a drive element. This inverter forms a pull-down drive circuit 23 which drives the transistor Q2 (output pull-down transistor) by charging and discharging the node N2.

In the example of FIG. 3, the equal potentials VDD are supplied to the drain of the transistor Q3 and the drain of the transistor Q6, respectively. However, different potentials may be supplied, as long as a normal operation of the unit shift register SR is ensured.

Subsequently, an operation of the unit shift register SRₖ of FIG. 3 will be described with reference to FIG. 4. Here, the description is based on an assumption that the clock signal CLK1 and the clock signal CLK2 are inputted to the clock terminal CK and the reset terminal RST of the unit shift register SRₖ, respectively (for example, corresponding to the unit shift registers SR₁ and SR₄ shown in FIG. 2).

For an easy description, if not otherwise specified, the following description is based on an assumption that: all of the H-level potentials of the clock signals CLK1 to CLK3 and the start pulse SP are equal to the high-side power supply potential VDD; the L-level potentials of the clock signals CLK1 to CLK3 and the start pulse SP are equal to the low-side power supply potential VSS, and this potential is 0V (VSS=0); and all of the threshold voltages of the respective transistors are equal, and the value thereof is Vth. As shown in FIG. 4, the clock signals CLK1 to CLK3 are repetitive signals phase-shifted from one another by one horizontal period (1H).

Firstly, it is assumed that in an initial state of the unit shift register SRₖ, the node N1 is at the L level and the node N2 is at the H level. At this time, the transistor Q1 is OFF (in a blocked state), and the transistor Q2 is ON (in the conducting state). Therefore, the output terminal OUT (output signal Gₖ) is kept at the L level, irrespective of the level of the clock terminal CK (clock signal CLK1) (hereinafter, this state will be referred to as a “reset state”). That is, the gate line GLk to which the unit shift register SRₖ is connected is in an unselected state. It is assumed that in the initial state, the clock signals CLK1 to CLK3, and the output signal Gₖ₋₁ of its immediately preceding stage (unit shift register SRₖ₋₁) are all at the L level.

When, from this state, the output signal Gₖ₋₁ of the immediately preceding stage is brought into the H level along with the rise of the clock signal CLK3, the transistor Q3 of this unit shift register SRₖ is turned ON. At this time, the node N2 is at the H level, and thus the transistor Q5 is ON. Since the transistor Q3 has its on-resistance sufficiently small (the drive capability is sufficiently high) as compared with the transistor Q5, the level of the node N1 rises.

Thereby, the transistor Q7 starts conducting, and the level of the node N2 drops. This lowers a resistance value of the transistor Q5, and therefore the level of the node N1 rapidly rises, so that the transistor Q7 becomes sufficiently ON. As a result, the node N2 becomes the L level (VSS). Accordingly, the transistor Q5 is turned OFF, to bring the node N1 into the H level (VDD−Vth).

When the node N1 becomes the H level and the node N2 becomes the L level in this manner, the transistor Q1 is turned ON and the transistor Q2 is turned OFF (hereinafter, this state will be referred to as a “set state”. However, at this time point, the clock signal CLK1 is at the L level, and therefore the output signal Gₖ is kept at the L level.

When the output signal Gₖ₋₁ of the immediately preceding stage returns to the L level along with the fall of the clock signal CLK3, the transistor Q3 is turned OFF. However, the transistors Q4, Q5 are also in the OFF state, and therefore the node N1 is kept at the H level in a high impedance state (floating state).

Then, when the clock signal CLK1 rises to the H level, the rise of the level is transmitted to the output terminal OUT through the ON-state transistor Q1, so that the level of the output signal Gₖ rises. At this time, because of the coupling through the capacitance element C1 and a gate capacitance (a capacitance between the gate and the drain, a capacitance between the gate and the source, and a capacitance between the gate and the channel) of the transistor Q1, the potential of the node N1 is boosted by a constant amount (boost amount ΔV) in accordance with the rise of the level of the output signal Gₖ. Therefore, even when the level of the output terminal OUT rises, the voltage between the gate and the source of the transistor Q1 is kept higher than the threshold voltage (Vth), and the transistor Q1 is kept at a low impedance.

Accordingly, the output signal Gₖ quickly becomes the H level following the rise of the clock signal CLK. At this time, the transistor Q1 is operated in a non-saturated region to charge the output terminal OUT. Therefore, the level of the output signal Gₖ rises to the same potential VDD as that of the clock signal CLK1, not involving a loss corresponding to the threshold voltage of the transistor Q1. In this manner, when the output signal Gₖ becomes the H level, the gate line GLk is in a selected state.

Then, when the clock signal CLK1 falls and returns to the L level, the output terminal OUT is discharged by the ON-state transistor Q1. Thus, the output signal Gₖ becomes the L level (VSS), and the gate line GLk returns to the unselected state.

Subsequently, when the clock signal CLK2 rises to the H level, the transistor Q4 is turned ON, and therefore the node N1 becomes the L level. Accordingly, the transistor Q7 is turned OFF, to bring the node N2 into the H level. That is, the unit shift register SRₖ returns to the reset state in which the transistor Q1 is OFF and the transistor Q2 is ON.

Subsequently, until the output signal Gₖ₋₁ of the immediately preceding stage is activated in the next frame period, a half latch circuit including the transistors Q5 to Q7 keeps the node N1 at the H level and the node N2 at the L level. Therefore, the unit shift register SRₖ is kept at the reset state. Accordingly, during a time period in which the gate line GLk is not selected, the output signal Gₖ is kept at the L level with a low impedance.

As described above, the unit shift register SRₖ is brought into the set state in accordance with activation of the signal (the start pulse SP or the output signal Gₖ₋₁ of the immediately preceding stage) inputted to the input terminal IN, and activates the output signal Gₖ of itself in an activation period of the signal (clock signal CLK1) inputted to the clock terminal CK at this time. Then, the unit shift register SRₖ returns to the reset state in accordance with activation of the signal (clock signal CLK2) inputted to the reset terminal RST, and subsequently keeps the output signal Gₖ at the L level.

Accordingly, in the gate-line drive circuit 30, as shown in FIG. 3, triggered by the activation of the start pulse SP inputted to the unit shift register SR₁, the output signals G₁, G₂, G₃ . . . are sequentially activated at the timings synchronized with the clock signals CLK1 to CLK3. Thereby, the gate-line drive circuit 30 can sequentially drive the gate lines GL₁, GL₂, GL₃ . . . in the predetermined scanning cycle.

In the example described above, the unit shift register SRₖ is operated based on three-phase clocks. However, the unit shift register SRₖ may also be operated using two-phase clock signals.

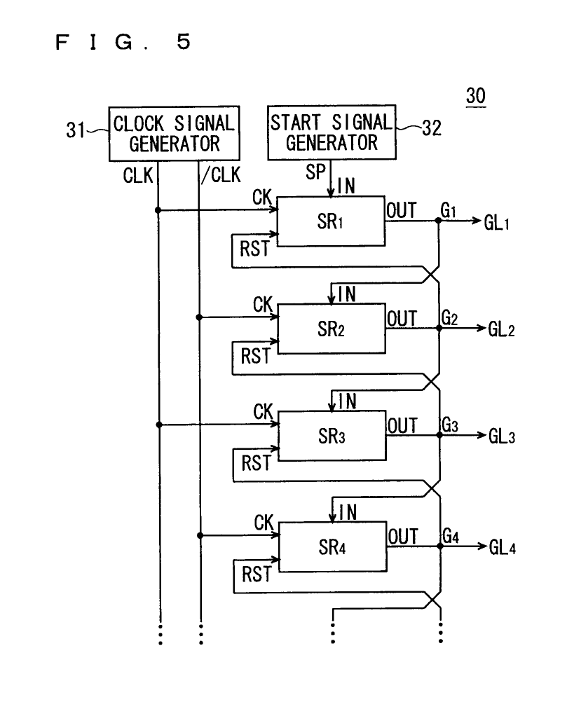

FIG. 5 shows a configuration of the gate-line drive circuit 30 which is operated based on two-phase clock signals. In this case as well, the gate-line drive circuit 30 is configured with a plurality of unit shift registers SR which are cascade-connected with one another. That is, inputted to the input terminal IN of the unit shift register SRₖ is the output signal Gₖ₋₁ of the unit shift register SRₖ₋₁ of the immediately preceding stage (the start pulse SP is inputted to the input terminal IN of the first-stage unit shift register SR₁).

The clock signal generator 31 of FIG. 5 outputs two-phase clock signals including clock signals CLK, /CLK having different phases (having their activation periods not overlapping each other). The clock signals CLK, /CLK have opposite phases, and are controlled such that they are alternately activated at the timings synchronized with the scanning cycle of the display device. Either one of the clock signals CLK, /CLK is supplied to the clock terminal CK of each unit shift register SR. More specifically, the clock signal CLK is supplied to the unit shift registers SR₁, SR₃, SR₅ . . . of odd-number stages, and the clock signal /CLK is supplied to the unit shift registers SR₂, SR₄, SR₆ . . . of the even-number stages.

An operation of the unit shift register SR in the gate-line drive circuit 30 configured as shown in FIG. 5 will be described with reference to FIG. 6. Here, an operation of the unit shift register SRₖ is described as a representative. It is assumed that the clock signal CLK is inputted to the clock terminal CK of the unit shift register SRₖ (the unit shift registers SR₁, SR₃, and the like, of FIG. 5 correspond thereto).

Firstly, a reset state in which the node N1 is at the L level and the node N2 is at the H level is assumed as an initial state of the unit shift register SRₖ. It is also assumed that the clock terminal CK (clock signal CLK), the reset terminal RST (a next-stage output signal Gₖ₊₁), and the input terminal IN (the output signal Gₖ₋₁ of the immediately preceding stage) are all at the L level.

When, from this state, the output signal Gₖ₋₁ of the immediately preceding stage is brought into the H level along with the rise of the clock signal /CLK, the transistor Q3 of this unit shift register SRₖ is turned ON, and the node N1 becomes the H level. Accordingly, the transistor Q7 is turned ON, to bring the node N2 into the L level. At this time, the transistor Q5 is turned OFF, and therefore the H-level potential of the node N1 becomes VDD−Vth.

As a result, the unit shift register SRₖ is brought into the set state in which the transistor Q1 is ON and the transistor Q2 is OFF. However, at this time point, the clock signal CLK is at the L level, and therefore the output signal Gₖ is kept at the L level.

When the output signal Gₖ₋₁ of the immediately preceding stage returns to the L level along with fall of the clock signal /CLK, the transistor Q3 is turned OFF. However, since the transistors Q4, Q5 are also in the OFF state, the node N1 is kept at the H level in a high impedance state.

Then, when the clock signal CLK rises, the rise of the level is transmitted to the output terminal OUT through the ON-state transistor Q1, so that the level of the output signal Gₖ rises. At this time, the potential of the node N1 is boosted by a constant amount (boost amount ΔV). Therefore, the transistor Q1 is operated in the non-saturated region. Accordingly, the output signal Gₖ quickly becomes the H level of the potential VDD following the rise of the clock signal CLK. As a result, the gate line GLk is brought into the selected state.

Then, when the clock signal CLK1 falls, the output terminal OUT is discharged by the ON-state transistor Q1. Thus, the output signal Gₖ becomes the L level (VSS), and the gate line GLk returns to the unselected state.

Subsequently, when the clock signal CLK2 rises, the transistor Q4 is turned ON, and therefore the node N1 becomes the L level. Accordingly, the transistor Q7 is turned OFF, to bring the node N2 into the H level. That is, the unit shift register SRₖ returns to the reset state in which the transistor Q1 is OFF and the transistor Q2 is ON.

Subsequently, until the output signal Gₖ₋₁ of the immediately preceding stage is activated in the next frame period, a half latch circuit including the transistors Q5 to Q7 keeps the node N1 at the H level and the node N2 at the L level. Therefore, the unit shift register SRₖ is kept at the reset state. Accordingly, during a time period in which the gate line GLk is not selected, the output signal Gₖ is kept at the L level with a low impedance.

As described above, in a case where the gate-line drive circuit 30 has the configuration shown in FIG. 5, the unit shift register SRₖ is operated in the same manner as a case of FIG. 2, except that the signal inputted to the reset terminal RST is the next-stage output signal Gₖ₊₁.

That is, the unit shift register SRₖ of FIG. 5 is also brought into the set state in accordance with activation of the signal (the start pulse SP or the output signal Gₖ₋₁ of the immediately preceding stage) inputted to the input terminal IN, and activates the output signal Gₖ of itself in an activation period of the signal (clock signal CLK) inputted to the clock terminal CK at this time. Then, the unit shift register SRₖ returns to the reset state in accordance with activation of the signal (clock signal /CLK) inputted to the reset terminal RST, and subsequently keeps the output signal Gₖ at the L level.

Accordingly, in the gate-line drive circuit 30, as shown in FIG. 6, triggered by the activation of the start pulse SP inputted to the unit shift register SR₁, the output signals G₁, G₂, G₃ . . . are sequentially activated at the timings synchronized with the clock signals CLK, /CLK.

In the configuration of FIG. 5, the next-stage output signal Gₖ₊₁ is inputted to the reset terminal RST of the unit shift register SRₖ. Therefore, the unit shift register SRₖ is not brought into the reset state (that is, the initial state mentioned above) unless the next-stage output signal Gₖ₊₁ is activated at least once. The unit shift register SR cannot perform a normal operation as shown in FIG. 6 without undergoing the reset state. Thus, in a case of the configuration of FIG. 5, it is necessary to perform, prior to the normal operation, a dummy operation of generating a dummy start pulse SP and transmitting it from the first-stage unit shift register SR to the last-stage unit shift register SR.

Alternatively, it may also be acceptable that a reset transistor is separately provided between the node N1 of the unit shift register SRₖ and the first power supply terminal S1 (low-side power supply potential VSS), and a reset operation of forcibly discharging the node N1 is performed prior to the normal operation. However, in this case, a reset signal line is separately required.

Here, the boost amount ΔV of the node N1 which is boosted by the activation of the output signal Gₖ in the unit shift register SRₖ will be described.

When in the unit shift register SRₖ of FIG. 3, the amplitude of the clock signal CLK inputted to the clock terminal CK is defined as Ac, the capacitance value of the capacitance element C1 is defined as C_{C1}, the gate capacitance of the transistor Q1 is defined as C_{Q1}, and the parasitic capacitance (except the gate capacitance of the transistor Q1) of the node N1 is defined as Cp; the boost amount ΔV is obtained as follows:

ΔV=Ac×(C_{C1}+C_{Q1})/(C_{C1}+C_{Q1}+Cp) (1)

In a case of the circuit of FIG. 3, the parasitic capacitance Cp corresponds to the sum of the gate capacitance C_{Q7} of the transistor Q7 and a capacitance component (wiring capacitance) CL involved in wiring of the node N1. As seen from Expression (1), the boost amount ΔV is increased by reducing the value of Cp.

In the unit shift register SRₖ, a high drive capability is required of the transistor Q1, because it is necessary that the unit shift register SRₖ charges and activates the gate line GLk by the output signal Gₖ at a high speed. When the boost amount ΔV is large, the voltage between the gate and the source of the transistor Q1 at a time of activation of the output signal Gₖ is large, and therefore its on-resistance is small. Thus, it is preferable that the boost amount ΔV is increased, because the drive capability of the unit shift register SRₖ can be improved to allow a higher-speed charge of the gate line GLk.

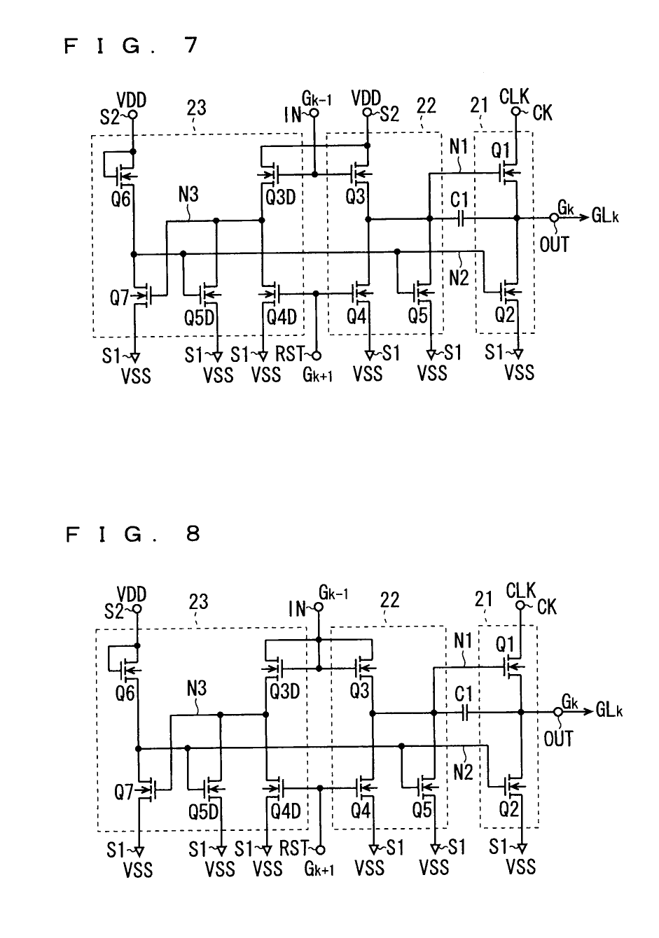

FIG. 8 of Japanese Patent Application Publication No. 2007-179660 discloses a unit shift register in which the parasitic capacitance Cp of the node N1 is reduced, which has been proposed by the present inventors. A circuit shown in this FIG. 8 is the same as the circuit shown in FIG. 3 of this specification, except that a diode-connected transistor Q8 is interposed between the gate (hereinafter referred to as a “node N3”) of the transistor Q7 and the node N1, and that a diode-connected transistor Q9 is connected between the input terminal IN and the node N3.

In FIG. 8 of Japanese Patent Application Publication No. 2007-179660, an anode and a cathode of the diode-connected transistor Q8 are the node N3 and the node N1, respectively. Therefore, when the node N1 is boosted, the transistor Q8 is turned OFF. That is, the node N1 and the node N3 are electrically separated from each other, and the gate capacitance C_{Q7} of the transistor Q7 no longer contributes to the parasitic capacitance Cp of the node N1. This provides an effect that the parasitic capacitance Cp at a time of boosting the node N1 becomes smaller and the boost amount ΔV of the node N1 becomes larger, as compared with in FIG. 3 of this specification (∵Expression (1)).

Here, in the circuit shown in FIG. 8 of Japanese Patent Application Publication No. 2007-179660, a current from the node N1 to the gate (node N3) of the transistor Q7 is blocked by the diode-connected transistor Q8. Thus, in shifting from the reset state (in which the node N1 is at the L level) to the set state (in which the node N1 is at the H level), in order to turn ON the transistor Q7 to bring the node N2 into the L level, means for bringing the node N3 into the H level when the node N1 is brought into the H level is separately required. The above-mentioned transistor Q9 serves this function, and functions so as to charge the node N3 in accordance with activation of the output signal Gₖ₋₁ of the immediately preceding stage.

On the other hand, the transistor Q8 allows passage of a current from the node N3 to the node N1. Therefore, when the unit shift register shown in FIG. 8 of Japanese Patent Application Publication No. 2007-179660 shifts from the set state to the reset state, the electric charge of the node N3 is discharged to the node N1 through the transistor Q8. However, since not only the drain but also the gate of the transistor Q8 is connected to the node N3, the voltage between the gate and the source of the transistor Q8 is reduced to increase its on-resistance as the discharge of the node N3 progresses. Accordingly, as compared with the circuit shown in FIG. 3 of this specification, the speed of discharging the node N3 is lowered, and the speed of response of the inverter made up of the transistors Q6, Q7 in the shift from the set state to the reset state is lowered. This may hinder an increase in the speed of the operation of the unit shift register.

The potential of the node N3 after the discharge is equal to the threshold voltage Vth of the transistor Q8, and the transistor Q7 is brought into a weak ON state in which a sub-threshold current flows. Therefore, as compared with the circuit shown in FIG. 3 of this specification, the speed of charging the node N2 by the transistor Q6 is lowered. This also causes the reduction in the speed of response of the inverter in the shift from the set state to the reset state.

In the following, a description will be given of a unit shift register of the present invention which can improve a drive capability by reducing the parasitic capacitance Cp of the node N1 and additionally can prevent a reduction in the speed of response of the inverter made up of the transistors Q6, Q7.

FIG. 7 is a circuit diagram of a unit shift register SRₖ according to a preferred embodiment of the present invention. This unit shift register SRₖ is the same as the circuit shown in FIG. 3, except that the gate (node N1) of the transistor Q1 and the gate (node N3) of the transistor Q7 are physically separated from each other, and that transistors Q3D, Q4D, Q5D which serve functions corresponding to the functions of the transistors Q3, Q4, Q5, respectively, are provided to the node N3.

As shown in FIG. 7, the output circuit 21 and the pull-up drive circuit 22 are configured in the same manner as in FIG. 3, and the transistors Q3D, Q4D, Q5D are provided in the pull-down drive circuit 23. The transistor Q3D is connected between the node N3 and the second power supply terminal S2, and the gate thereof is connected to the input terminal IN. The transistor Q4D is connected between the node N3 and the first power supply terminal S1, and the gate thereof is connected to the reset terminal RST. The transistor Q5D is connected between the node N3 and the first power supply terminal S1, and the gate thereof is connected to the node N2 (an output end of the inverter made up of the transistors Q6, Q7).

An operation of the unit shift register SR according to this preferred embodiment will be described. Here, it is assumed that the unit shift registers SR are connected as shown in FIG. 5 to form the gate-line drive circuit 30, and driven by using two-phase clock signals CLK, /CLK. Additionally, here, too, the k-th unit shift register SRₖ will be described as a representative, and it is assumed that the clock signal CLK is inputted to the clock terminal CK of the unit shift register SRₖ.

Firstly, the reset state in which the node N1 is at the L level (VSS) and the node N2 is at the H level (VDD−Vth) is assumed as an initial state of the unit shift register SRₖ. When, from this state, the output signal Gₖ₋₁ of the immediately preceding stage is activated, the transistor Q3 (first charge circuit) and the transistor Q3D (second charge circuit) are turned ON. At this time, since the node N2 is at the H level, the transistors Q5, Q5D are turned ON. The transistor Q3 is set such that its on-resistance is sufficiently small as compared with the transistor Q5, and the transistor Q3D is set such that its on-resistance is sufficiently small as compared with the transistor Q5D. Therefore, the nodes N1, N3 are brought into the H level.

Since the node N3 is brought into the H level, the transistor Q7 is turned ON, to bring the node N2 into the L level. Thereby, the transistors Q5, Q5D are turned OFF, so that the potentials of the nodes N1, N3 rise to VDD−Vth.

As a result, the set state in which the node N1 is at the H level and the node N2 is at the L level is established, and the output circuit 21 is brought into a state in which the transistor Q1 is ON and the transistor Q2 is OFF. However, at this time point, the clock signal CLK supplied to the clock terminal CK is at the L level, and therefore the output terminal OUT (output signal Gₖ) remains at the L level (VSS) with a low impedance.

When the output signal Gₖ₋₁ of the immediately preceding stage is deactivated, the transistors Q3, Q3D are turned OFF. However, the nodes N1, N3 are kept at the H level by the parasitic capacitance (that is, nodes N1, N3 are at the H level in a high impedance state (floating state)). Therefore, the unit shift register SRₖ is kept in the set state.

Subsequently, when the clock signal CLK is activated, the output terminal OUT is charged through the ON-state transistor Q1, to bring the output signal Gₖ into the H level. At this time, because of the coupling through the capacitance element C1 and a gate capacitance (a capacitance between the gate and the drain, a capacitance between the gate and the source, and a capacitance between the gate and the channel) of the transistor Q1, the node N1 is boosted by a constant potential (boost amount ΔV) along with a rise of the potential of the output terminal OUT. Accordingly, the transistor Q1 is operated in the non-saturated region, and the H-level potential of the output signal Gₖ becomes the same potential VDD as the H-level potential of the clock signal CLK.

In the unit shift register SRₖ shown in FIG. 7, the node N1 and the node N3 are separated from each other. Therefore, the gate capacitance C_{Q7} of the transistor Q7 does not contribute to the parasitic capacitance Cp of the node N1, and the parasitic capacitance Cp of the node N1 is smaller as compared with the circuit shown in FIG. 3. Thus, the boost amount ΔV of the node N1 is large (∵Expression (1)), and the on-resistance of the transistor Q1 can be reduced. Consequently, the speed of rise of the output signal Gₖ is improved.

Subsequently, when the clock signal CLK is deactivated, the output terminal OUT is discharged through the transistor Q1, and the output signal Gₖ returns to the L level. At this time, the potential of the node N1 returns to the value (VDD−Vth) before the boosting, but the transistor Q1 is kept ON. Therefore, the output terminal OUT is at the L level with a low impedance.

When the output signal Gₖ becomes the H level before, the next-stage unit shift register SRₖ₊₁ is brought into the set state. Therefore, when the clock signal /CLK is activated next time, the next-stage output signal Gₖ₊₁ becomes the H level.

Thus, in the unit shift register SRₖ, the transistor Q4 (first discharge circuit) and the transistor Q4D (second discharge circuit) are turned ON, and the nodes N1, N3 are discharged into the L level (VSS). Accordingly, the transistor Q7 is turned OFF, and the node N2 is charged by the transistor Q6, into the H level.

That is, the unit shift register SRₖ returns to the reset state, in which the transistor Q1 is OFF and the transistor Q2 is ON. Thus, the output terminal OUT is kept at the L level with a low impedance. Moreover, since the transistors Q5, Q5D are turned ON, the nodes N1, N3 are also at the L level with a low impedance.

Then, along with the deactivation of the clock signal /CLK, the next-stage output signal Gₖ₊₁ becomes the L level. Thereby, in the unit shift register SRₖ, the transistors Q4, Q4D are turned OFF, but the transistors Q5, Q5D are ON. Therefore, both of the nodes N1, N3 are kept at the L level with a low impedance.

Subsequently, until the output signal Gₖ₋₁ of the immediately preceding stage is activated again in the next frame, a half latch circuit including the transistors Q5D, Q6, Q7 keeps the node N2 at the H level and the node N3 at the L level. Therefore, the transistor Q5 is kept ON, and the node N1 is kept at the L level with a low impedance. Accordingly, in this period, the unit shift register SRₖ is kept in the reset state, and the output signal Gₖ is kept at the L level with a low impedance.

In this manner, the unit shift register SRₖ shown in FIG. 7 can perform the same operation as the circuit shown in FIG. 3 does. That is, when the signal (the output signal Gₖ₋₁ of the immediately preceding stage) of the input terminal IN is activated, the unit shift register SRₖ shown in FIG. 7 is also brought into the set state, and activates the output signal Gₖ in synchronization with the signal (clock signal CLK or /CLK) of the clock terminal CK, while when the signal (the next-stage output signal Gₖ₊₁) of the reset terminal RST is activated, the unit shift register SRₖ shown in FIG. 7 returns to the reset state to keep the output signal Gₖ at the deactivation level.

In an example shown here, the unit shift register SRₖ shown in FIG. 7 is operated based on the two clock signals CLK, /CLK. However, needless to say, the unit shift register SRₖ may be operated by using clock signals of three or more phases.

As described above, the unit shift register shown in FIG. 8 of Japanese Patent Application Publication No. 2007-179660 involves the following problem. That is, when shifting to the reset state, the node N3 is discharged through the diode-connected transistor. Therefore, as the discharge of the node N3 progresses, the speed of the discharge is lowered, and moreover the potential of the node N3 after the discharge becomes Vth, so that the transistor Q7 is brought into a weak ON state. Thus, the speed of charging the node N2 is lowered.

On the other hand, in the unit shift register SRₖ shown in FIG. 7, the voltage between the gate and the source of the node N3 is discharged through the transistor Q4D having reached VDD (the amplitude of the next-stage output signal Gₖ₊₁). Therefore, even when the discharge of the node N3 progresses, the speed of the discharge is not lowered. Furthermore, since the node N3 is lowered to the potential VSS, the transistor Q7 can be completely turned OFF, so that the speed of charging the node N2 is not lowered, either. Accordingly, the unit shift register SRₖ of this preferred embodiment enables an increase in the speed of the operation.

[First Modification]

In the unit shift register SRₖ shown in FIG. 7, the drains of the transistors Q3, Q3D are connected to the second power supply terminal S2 to which a constant high-side power supply potential VDD is supplied. Here, it may be also acceptable that they are connected to a first input terminal IN1 to which the output signal Gₖ₋₁ of the immediately preceding stage is supplied as shown in FIG. 8. As a result, wiring for supplying the high-side power supply potential VDD to the transistors Q3, Q3D can be omitted. Thus, an effect of making a circuit layout easy.

In the configuration shown in FIG. 7, as compared with the configuration shown in FIG. 8, an effect is obtained that a load capacitance driven by the output signal G of each unit shift register SR is reduced to improve the speeds of rise and fall of the output signal G of each stage.

In FIG. 7, the sources of the transistors Q4, Q4D are fixed at the low-side power supply potential VSS. However, another signal may be supplied to the sources of the transistors Q4, Q4D, as long as the transistors Q4, Q4D can discharge the nodes N1, N3 in accordance with activation of the signal (the next-stage output signal Gₖ₊₁) of the reset signal RST. In other words, a signal whose activation period does not overlap the activation period of the signal (the next-stage output signal Gₖ₊₁) of the reset signal RST may be supplied to the transistors Q4, Q4D.

As a specific example thereof, it is conceivable that the sources of the transistors Q4, Q4D of the unit shift register SRₖ are connected to the clock terminal CK of the unit shift register SRₖ. For example, if the clock signal CLK is supplied to the clock terminal CK in the unit shift register SRₖ, the clock signal CLK is supplied to the sources of the transistors Q4, Q4D, too. The clock signal supplied to the clock terminal CK of the unit shift register SRₖ has the same phase as that of the output signal Gₖ of this unit shift register SRₖ, and its activation period does not overlap the activation period of the next-stage output signal Gₖ₊₁. Here, in this case, it should be noted that power consumption of the clock signal generator 31 increases.

[Second Modification]

In the unit shift register SRₖ shown in FIG. 7, at a time point when the output signal Gₖ₋₁ of the immediately preceding stage becomes the H level so that the transistor Q3D is turned ON, the transistor Q5D is in the ON state. Since the transistor Q3D is set such that its on-resistance is sufficiently small as compared with the transistor Q5D, the node N3 is charged into the H level, but the electric charge is discharged through the transistor Q5D. This is a factor in lowering the speed of charging the node N3. There is also a problem that the area where the transistor Q3D is formed is increased because it is necessary to increase the width of the gate of the transistor Q3D in order to reduce the on-resistance.

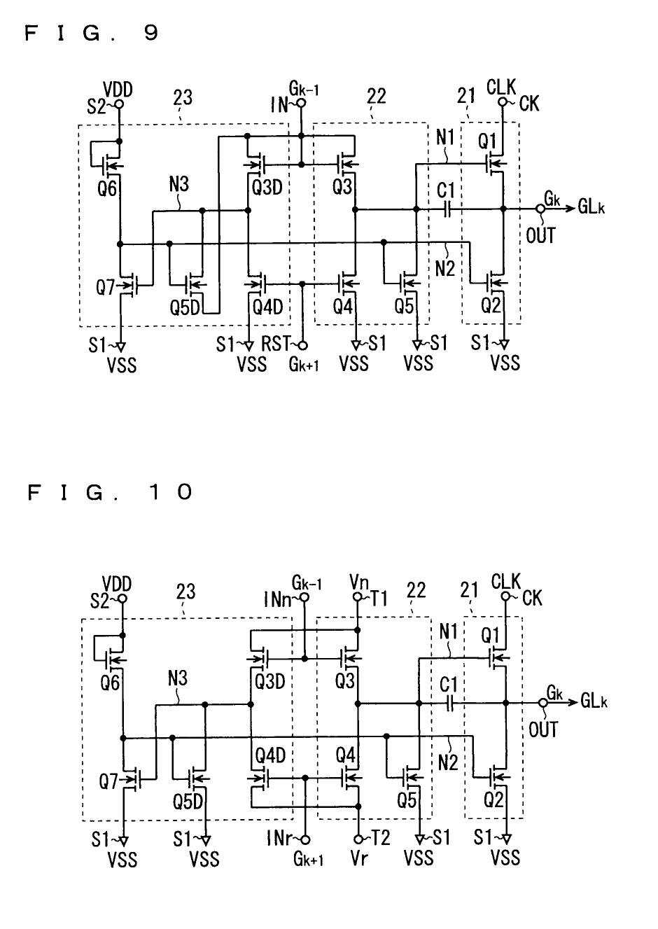

FIG. 9 is a circuit diagram of a unit shift register SRₖ according to a second modification of this preferred embodiment. This unit shift register SRₖ is realized by connecting the source of the transistor Q5D to the input terminal IN in the circuit shown in FIG. 8. Although a modification of the configuration shown in FIG. 8 is shown here, the drains of the transistors Q3, Q3D may be connected to the second power supply terminal S2 as shown in FIG. 7.

In the unit shift register SRₖ shown in FIG. 9, when the output signal Gₖ₋₁ of the immediately preceding stage becomes the H level (VDD) so that the transistor Q3D is turned ON, the source of the transistor Q5D becomes the H level (VDD), and therefore the transistor Q5D is turned OFF. Thus, the transistor Q3D can charge the node N3 at a high speed.

In the configuration shown in FIG. 9, it is not necessary that the on-resistance of the transistor Q3D is smaller than the on-resistance of the transistor Q5D. That is, it is not necessary to increase the width of the gate of the transistor Q5D, and the area where the transistor Q5D is formed can be reduced.

The source of the transistor Q5 may be connected to the input terminal IN, similarly to the source of the transistor Q5D.

[Third Modification]

Here, the present invention is applied to a unit shift register used in a gate-line drive circuit capable of bi-directional scanning. FIG. 10 is a circuit diagram of a unit shift register SRₖ according to a third modification of this preferred embodiment.

In this modification, first and second voltage signals Vn, Vr for controlling a shift direction of a signal are supplied to each of the unit shift registers SR included in the gate-line drive circuit 30, and each of the unit shift registers SR includes a first voltage signal terminal T1 and a second voltage signal terminal T2. A first voltage signal Vn is supplied to the first voltage signal terminal T1. A second voltage signal Vr is supplied to the second voltage signal terminal T2.

The first and second voltage signals Vn, Vr are signal complementary to each other. To shift the direction of the signal from the immediately preceding stage to the subsequent-stage (in the order of the unit shift registers SR₁, SR₂, SR₃, . . . ) (this direction is defined as a “forward direction”), the first voltage signal Vn is set at the H level and the second voltage signal Vr is set at the L level. On the other hand, to shift the direction of the signal from the subsequent-stage to the immediately preceding stage (in the order of the unit shift registers SRₙ, SRₙ₋₁, SRₙ₋₂, . . . ) (this direction is defined as a “reverse direction”), the second voltage signal Vr is set at the H level and the first voltage signal Vn is set at the L level. For the purpose of facilitating the description, it is assumed that the H level potentials of the first and second voltage signals Vn, Vr are the high-side power supply potential VDD, and the L-level potential thereof the low-side power supply potential VSS.

The unit shift register SRₖ shown in FIG. 10 is configured by, in the circuit shown in FIG. 7, connecting one-side current electrodes of the transistors Q3, Q3D to the first voltage signal terminal T1 and connecting one-side current electrodes of the transistors Q4, Q4D to the second voltage signal terminal T2. That is, the transistor Q3 is connected between the node N1 and the first voltage signal terminal T1, and the transistor Q4 is connected between the node N1 and the second voltage signal terminal T2. The transistor Q3D is connected between the node N3 and the first voltage signal terminal T1, and the transistor Q4D is connected between the node N3 and the second voltage signal terminal T2.

In the unit shift register SRₖ shown in FIG. 10, the gates of the transistors Q3, Q3D are connected to a forward direction input terminal INn (first input terminal), and the gates of the transistors Q4, Q4D are connected to a reverse direction input terminal INr (second input terminal). The output signal Gₖ₋₁ of the immediately preceding stage is inputted to the forward direction input terminal INn, similarly to the input terminal IN of FIG. 7. The next-stage output signal Gₖ₊₁ is inputted to the reverse direction input terminal INr, similarly to the reset terminal RST of FIG. 7.

In a case where the gate-line drive circuit 30 performs a forward-direction shifting operation (hereinafter simply referred to as a “time of a forward-direction shift”), the first voltage signal Vn is set at the H level (VDD), and the second voltage signal Vr is set at the L level (VSS) (first operation mode). In this case, the circuit of FIG. 10 is equivalent to the circuit of FIG. 7. Therefore, the unit shift register SRₖ shown in FIG. 10 can perform the forward-direction shift, similarly to the unit shift register SRₖ shown in FIG. 7.

In this case, the transistors Q3, Q4 (first charge/discharge circuit) are operated so as to charge the node N1 in accordance with the activation of the signal (the output signal Gₖ₋₁ of the immediately preceding stage) of the forward direction input terminal INn, and discharge the node N1 in accordance with the activation of the signal (the next-stage output signal Gₖ₊₁) of the reverse direction input terminal INr. On the other hand, the transistors Q3D, Q4D (second charge/discharge circuit) are operated so as to charge the node N3 in accordance with the activation of the signal of the forward direction input terminal INn, and discharge the node N3 in accordance with the activation of the signal of the reverse direction input terminal INr.

Therefore, at a time of the forward-direction shift, the unit shift register SRₖ of FIG. 10 is brought into the set state when the signal of the forward direction input terminal INn is activated, and activates the output signal Gₖ in synchronization with the signal (the clock signal CLK or /CLK) of the clock terminal CK. When the signal of the reverse direction input terminal INr is activated, the unit shift register SRₖ returns to the reset state, and keeps the output signal Gₖ at the deactivation level.

On the other hand, when the gate-line drive circuit 30 performs a reverse-direction shifting operation (hereinafter simply referred to as a “time of a reverse-direction shift”), the first voltage signal Vn is set at the L level (VSS), and the second voltage signal Vr is set at the H level (VDD) (second operation mode). Accordingly, in a case of a reverse-direction shift, contrary to the forward-direction shift, the transistors Q3, Q3D function as transistors for discharging the nodes N1, N3, respectively, and the transistors Q4, Q4D function as transistors for charging the nodes N1, N3, respectively. That is, as compared with a case of the forward-direction shift, the operation of the transistors Q3, Q3D and the operation of the transistors Q4, Q4D replace each other.

Thus, the transistors Q3, Q4 (first charge/discharge circuit) are operated so as to charge the node N1 in accordance with the activation of the signal (the next-stage output signal Gₖ₊₁) of the reverse direction input terminal INr, and discharge the node N1 in accordance with the activation of the signal (the output signal Gₖ₋₁ of the immediately preceding stage) of the forward direction input terminal INn. On the other hand, the transistors Q3D, Q4D (second charge/discharge circuit) are operated so as to charge the node N3 in accordance with the activation of the signal of the reverse direction input terminal INr, and discharge the node N3 in accordance with the activation of the signal of the forward direction input terminal INn.

Accordingly, at a time of the reverse-direction shift, the unit shift register SRₖ of FIG. 10 is brought into the set state when the signal of the reverse direction input terminal INr is activated, and activates the output signal Gₖ in synchronization with the signal (the clock signal CLK or /CLK) of the clock terminal CK. When the signal of the forward direction input terminal INn is activated, the unit shift register SRₖ returns to the reset state, and keeps the output signal Gₖ at the deactivation level.

[Fourth Modification]

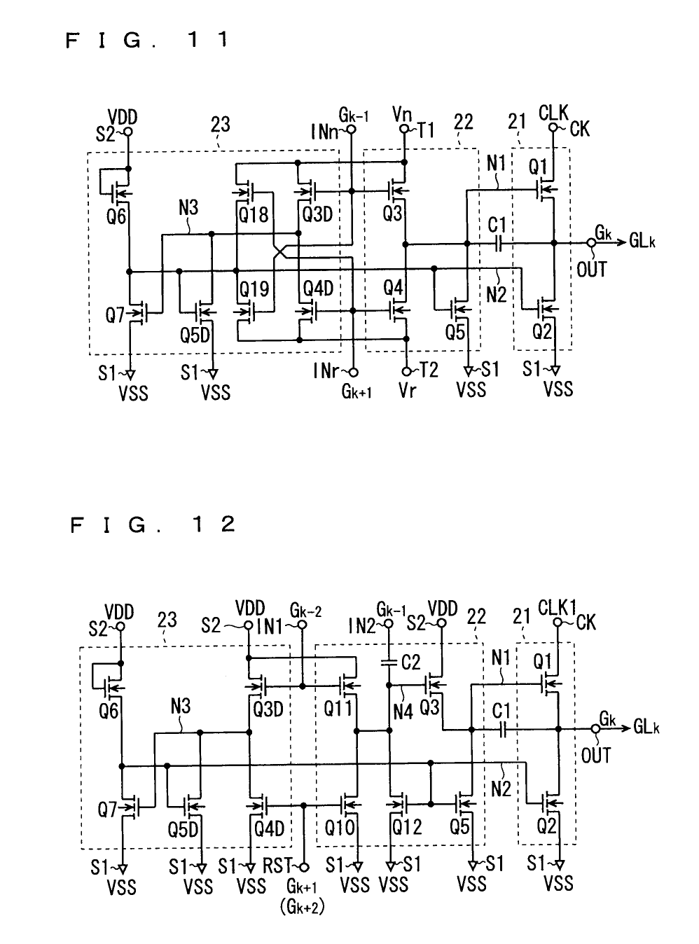

FIG. 11 is a circuit diagram of a unit shift register SRₖ according to a fourth modification of the preferred embodiment. This unit shift register SRₖ is realized by providing transistors Q18, Q19 connected to the node N2 in the circuit of FIG. 10. The transistor Q18 is connected between the node N2 and the first voltage signal terminal T1, and the gate thereof is connected to the reverse direction input terminal INr (the gates of the transistors Q4, Q4D). The transistor Q19 is connected between the node N2 and the second voltage signal terminal T2, and the gate thereof is connected to the forward direction input terminal INn (the gates of the transistors Q3, Q3D). Each of the transistors Q18, Q19 is set such that its on-resistance is sufficiently small as compared with the transistor Q6.

An operation of this unit shift register SRₖ is almost the same as that of the circuit of FIG. 10, and therefore a description thereof is omitted. However, the operation of this unit shift register SRₖ is different from that of FIG. 10, in that the charge and discharge of the node N2 are performed mainly by the transistors Q18, Q19.

That is, in the unit shift register SRₖ, at a time of the forward-direction shift for example, when the output signal Gₖ₋₁ of the immediately preceding stage is activated, the transistor Q19 discharges the node N2 into the L level, and therefore the transistors Q5, Q5D are turned OFF. Thus, unlike in FIG. 10, at a time point when the transistors Q3, Q3D start charging the nodes N1, N3, the transistors Q5, Q5D are turned OFF. This can shorten a time period for charging the nodes N1, N3.

At a time of the reverse-direction shift, when the next-stage output signal Gₖ₊₁ is activated, the transistor Q18 discharges the node N2 into the L level, and therefore the transistors Q5, Q5D are turned OFF. Thus, at a time point when the transistors Q4, Q4D start charging the nodes N1, N3, the transistors Q5, Q5D are turned OFF. This can shorten a time period for charging the nodes N1, N3.

In this manner, according to this modification, the speed of charging the nodes N1, N3 is improved, so that the speed of the operation of the unit shift register SRₖ can be increased.

[Fifth Modification]

Here, the present invention is applied to a unit shift register disclosed in Japanese Patent Application Publication No. 2007-257813 which is a patent application filed by the present inventor.

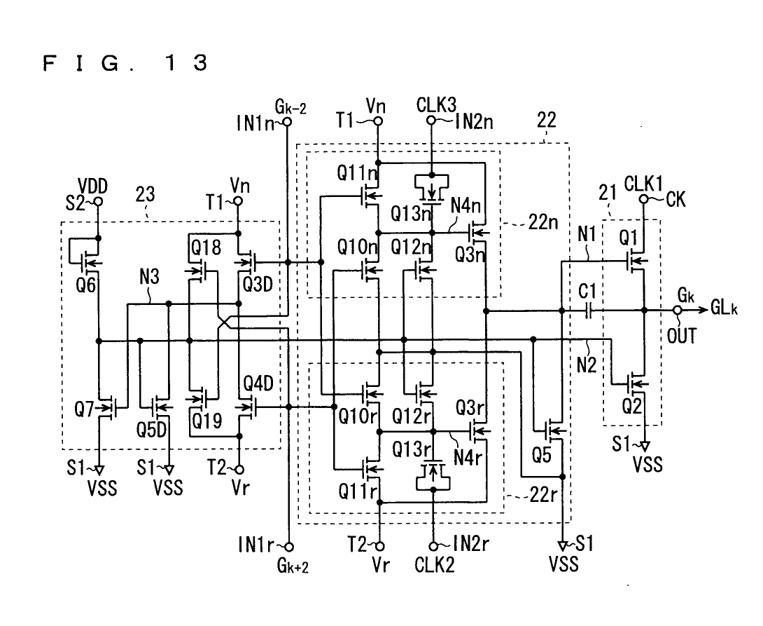

FIG. 12 is a circuit diagram of a unit shift register SRₖ according to a fifth modification of this preferred embodiment. This unit shift register SRₖ is different from the circuit of FIG. 7, in the configuration of the pull-up drive circuit 22. The unit shift register SRₖ includes a first input terminal IN1 to which an output signal Gₖ₋₂ of the second preceding stage is inputted, and a second input terminal IN2 to which an output signal Gₖ₋₁ of the immediately preceding stage is inputted.

The pull-up drive circuit 22 includes transistors Q3, Q5, Q10 to Q12, and a capacitance element C2 which will be described below. The transistor Q3 is connected between the node N1 and the second power supply terminal S2. Here, a node connected to the gate of the transistor Q3 is defined as a “node N4”. The transistor Q5 is connected between the node N1 and the first power supply terminal S1, and the gate thereof is connected to the node N2.

The transistor Q11 is connected between the node N4 and the second power supply terminal S2, and the gate thereof is connected to the first input terminal IN1. The transistor Q10 is connected between the node N4 and the first power supply terminal S1, and the gate thereof is connected to the reset terminal RST. The transistor Q12 is connected between the node N4 and the first power supply terminal S1, and the gate thereof is connected to the node N2. The capacitance element C2 (boost element) is connected to the node N4 and the second input terminal 1N2.

Next, an operation of the unit shift register SRₖ of FIG. 12 will be described. The gate-line drive circuit 30 using this unit shift register SRₖ is driven by using the three-phase clock signals CLK1 to CLK3 as shown in FIG. 2. Here, it is assumed that the clock signal CLK1 is inputted to the clock terminal CK of the unit shift register SRₖ.

In the unit shift register SRₖ, when the output signal Gₖ₋₂ of the unit shift register SRₖ₋₂ of the second preceding stage is activated, the transistor Q11 (first charge circuit) of the pull-up drive circuit 22 and the transistor Q3D (second charge circuit) of the pull-down drive circuit 23 are turned ON, to charge the nodes N3, N4 into the H level. Accordingly, the transistor Q7 is turned ON, to bring the node N2 into the L level, so that the transistors Q5, Q5D, Q12 are turned OFF. Here, when the node N4 becomes the H level, the transistor Q3 is turned ON and the node N1 is also charged. At this time, the potential of the node N1 is VDD−2Vth at the maximum.

Subsequently, when the output signal Gₖ₋₂ of the second preceding stage is deactivated, the transistors Q3D, Q11 are turned OFF, but the nodes N3, N4 are kept at the H level by parasitic capacitances (not shown) of the nodes N3, N4, respectively.

Then, when the output signal Gₖ₋₁ of the unit shift register SRₖ₋₁ of the immediately preceding stage is activated, the node N4 is boosted by coupling through the capacitance element C2 in the unit shift register SRₖ. If the parasitic capacitance of the node N4 is sufficiently smaller than the capacitance value of the capacitance element C2, the node N4 is boosted to the same extent as the amplitude (VDD) of the output signal Gₖ₋₁ of the immediately preceding stage. Thereby, the transistor Q3 is operated in the non-saturated region, and the potential of the node N1 rises to VDD. That is, the potential of the node N1 becomes higher than that in the circuit of FIG. 7 by Vth, so that the on-resistance of the transistor Q1 can be reduced.

When the clock signal CLK1 is activated, the output terminal OUT is charge d through the ON-state transistor Q1, to bring the output signal Gₖ into the H level. Then, when the clock signal CLK1 is deactivated, the output terminal OUT is discharged through the transistor Q1, to bring the output signal Gₖ into the L level. Since the on-resistance of the transistor Q1 is small as described above, the rising speed and the falling speed of the output signal Gₖ are increased as compared with the circuit of FIG. 7.

Then, when the next-stage output signal Gₖ₊₁ is activated, the transistor Q10 (first discharge circuit) and the transistor Q4D (second discharge circuit) are turned ON, to discharge the nodes N4, N3 into the L level. Accordingly, the transistor Q7 is turned OFF, and the node N2 is charged by the transistor Q6 and brought into the H level. Therefore, the transistor Q5 is turned ON, and the node N1 is brought into the L level.

When next-stage output signal Gₖ₊₁ is deactivated, the transistors Q4D, Q10 are turned OFF. However, since the transistors Q5, Q5D, Q12 are kept ON, the nodes N1, N3, N3 are kept at the L level with a low impedance.

In the unit shift register disclosed in Japanese Patent Application Publication No. 2007-257813, the transistor Q7 is directly connected to the node N4, and therefore the parasitic capacitance of the node N4 is larger than that in the circuit of FIG. 12. In other words, in the circuit of FIG. 12, the parasitic capacitance of the node N4 is small, and therefore when the capacitance element C2 boosts the node N4, the potential of the node N4 can be greatly raised. Thereby, the speed of charging the node N1 by the transistor Q3 is improved, so that the speed of the operation can be increased.

The signal inputted to the reset terminal RST may be an output signal Gₖ+₂ of the second next stage. Additionally, it may be acceptable to apply the first modification, and the drains of the transistors Q3D, Q11 may be connected to the first input terminal IN1, or the clock signal CLK1 (the signal having a different phase from the phase of the signal of the reset terminal RST) may be inputted to the sources of the transistors Q4D, Q10. Moreover, it may be acceptable to apply the second modification, and the sources of the transistors Q5, Q5D may be connected to the first input terminal IN1.

[Sixth Modification]

Here, the techniques of the above-described fourth and fifth modifications (FIGS. 11 and 12) are combined, to propose a unit shift register in which the rising speed of the output signal is high and the signal shifting direction can be switched.

FIG. 13 is a circuit diagram of a unit shift register SRₖ according to a sixth modification of this preferred embodiment. This unit shift register SRₖ also includes the output circuit 21, the pull-up drive circuit 22, and the pull-down drive circuit 23. This unit shift register SR has four input terminals of a first forward direction input terminal IN1n (first input terminal), a first reverse direction input terminal IN1r (second input terminal), a second forward direction input terminal IN2n (third input terminal), and a second reverse direction input terminal IN2r (fourth input terminal).

The output signal Gₖ₋₂ of the second preceding stage is inputted to the first forward direction input terminal IN1n. A clock signal whose phase is delayed by one horizontal period with respect to the signal (the output signal Gₖ₋₂ of the second preceding stage) inputted to the first forward direction input terminal IN1n is supplied to the second forward direction input terminal IN2n at a time of the forward-direction shift. The phase of this clock signal is advanced by one horizontal period with respect to the signal supplied to the clock terminal CK of the output circuit 21 at a time of the forward-direction shift.

The output signal Gₖ₊₂ of the second next stage is inputted to the first reverse direction input terminal IN1r. A clock signal whose phase is delayed by one horizontal period with respect to the signal (the output signal Gₖ₊₂ of the second next stage) inputted to the first reverse direction input terminal IN1r is supplied to the second reverse direction input terminal IN2r at a time of the reverse-direction shift. The phase of this clock signal is advanced by one horizontal period with respect to the signal supplied to the clock terminal CK of the output circuit 21 at a time of the reverse-direction shift.

Here, it is assumed that the gate-line drive circuit 30 is driven by using three-phase clock signals CLK1 to CLK3, and that the order (the relationship among the phases) of activating these clock signals CLK1, CLK2, CLK3 is changed in accordance with the signal shift direction. That is, at a time of the forward-direction shift, the clock signals CLK1 to CLK3 are activated in the order of CLK1, CLK2, CLK3, CLK1 . . . , and at a time of the reverse-direction shift, the clock signals CLK1 to CLK3 are activated in the order of CLK3, CLK2, CLK1, CLK3 . . . . In this case, as shown in FIG. 13, for example, in a unit shift register SRₖ in which the clock signal CLK1 is inputted to the clock terminal CK, the clock signal CLK3 is inputted to the second forward direction input terminal IN2n, and the clock signal CLK2 is inputted to the second reverse direction input terminal IN2r.

The configurations of the output circuit 21 and the pull-down drive circuit 23 are the same as shown in FIG. 11. However, in the pull-down drive circuit 23, the gates of the transistors Q3D, Q19 are connected to the first forward direction input terminal IN1n, and the gates of the transistors Q4D, Q18 are connected to the first reverse direction input terminal IN1r. Here, too, a node connected to the gate of the transistor Q1 is defined as the “node N1”, a node connected to the gate of the transistor Q2 is defined as the “node N2”, and a node connected to the gate of the transistor Q7 is defined as the “node N3”.

The pull-up drive circuit 22 includes the transistor Q5, a forward direction pull-up drive circuit 22n (first charge circuit), and a reverse direction pull-up drive circuit 22r (second charge circuit). Similarly to FIG. 12, the transistor Q5 has the gate connected to the node N2, and is connected between the node N1 and the first power supply terminal S1.

The forward direction pull-up drive circuit 22n includes transistors Q3n, Q10n to Q13n which will be described below. The transistor Q3n is connected between the node N1 and the first voltage signal terminal T1, and supplies the first voltage signal Vn to the node N1. Here, a node connected to the gate of the transistor Q3n is defined as a “node N4n”.

The transistor Q10n is connected between the node N4n and the first power supply terminal S1, and the gate thereof is connected to the first reverse direction input terminal IN1r. The transistor Q11n (first charge element) is connected between the node N4n and the first voltage signal terminal T1, and the gate thereof is connected to the first forward direction input terminal IN1n. The transistor Q12n is connected between the node N4n and the first power supply terminal S1, and the gate thereof is connected to the node N2. The transistor Q13n has the gate thereof is connected to the node N4n, and both of two current electrodes (the source and the drain) are connected to the second forward direction input terminal IN2n.

The reverse direction pull-up drive circuit 22r includes transistors Q3r, Q10r to Q13r which will be described below. The transistor Q3r is connected between the node N1 and the second voltage signal terminal T2, and supplies the second voltage signal Vr to the node N1. Here, a node connected to the gate of the transistor Q3r is defined as a “node N4r”.

The transistor Q10r is connected between the node N4r and the first power supply terminal S1, and the gate thereof is connected to the first forward direction input terminal IN1n. The transistor Q11r (second charge element) is connected between the node N4r and the second voltage signal terminal T2, and the gate thereof is connected to the first reverse direction input terminal IN1r. The transistor Q12r is connected between the node N4r and the first power supply terminal S1, and the gate thereof is connected to the node N2. The transistor Q13r has the gate thereof connected to the node N4r, and both of two current electrodes are connected to the second reverse direction input terminal IN2r.

The transistors Q13n, Q13r function as capacitance elements. A field effect transistor is an element in which when a voltage equal to or higher than a threshold voltage is applied to the gate electrode, a conductive channel is formed at a portion immediately below the gate electrode with interposition of a gate insulating film within a semiconductor substrate, to thereby electrically connect the drain and the source to each other so that they are conducting. Accordingly, the field effect transistor in a conducting state has a constant electrostatic capacitance (gate capacitance) between the gate and the channel, and can function as a capacitance element in which the channel and the gate electrode within the semiconductor substrate serve as terminals and the gate insulating film serves as a dielectric layer.

Therefore, the transistor Q13n (first boost element) selectively functions as a capacitance element in accordance with the voltage between the node N4n and the second forward direction input terminal IN2n (functions as a capacitance element only while the node N4n is at the H level). The transistor Q13r (second boost element) selectively functions as a capacitance element in accordance with the voltage between the node N4r and the second reverse direction input terminal IN2r (functions as a capacitance element only while the node N4r is at the H level). In this manner, the capacitance element in which the gate and the channel of a MOS transistor are used as electrodes is referred to as a “MOS capacitance element”.

In the following, an operation of the unit shift register SRₖ shown in FIG. 13 will be described. At a time of the forward-direction shift, the first voltage signal Vn is set at the H level (VDD), and the second voltage signal Vr is set at the L level (VSS) (first operation mode). In this case, the first voltage signal Vn functions as activation-level power, and the forward direction pull-up drive circuit 22n is in the activated state (operable state). Since the drains (first voltage signal terminal T1) of the transistors Q3n, Q11n are fixed at the H level (VDD), the forward direction pull-up drive circuit 22n and the transistor Q5 form a circuit equivalent to the pull-up drive circuit 22 of FIG. 12 (the transistor Q13n (MOS capacitance element) functions similarly to the capacitance element C2 when the node N4n is at the H level).

On the other hand, no activation-level power is supplied to the reverse direction pull-up drive circuit 22r, and reverse direction pull-up drive circuit 22r is in a resting state. In this case, no electric charge is supplied to the node N1 through the transistor Q3r. The transistor Q11r cannot charge the node N4r, and no channel is formed in the transistor Q13r (MOS capacitance element), so that the node N4r cannot be boosted. Therefore, the node N4r is kept at the L level, and the transistor Q3r kept in the OFF state.

The transistors Q3D, Q4D (charge/discharge circuit) of the pull-down drive circuit 23 are operated so as to charge the node N3 in accordance with the activation of the signal (the output signal Gₖ₋₂ of the second preceding stage) of the first forward direction input terminal IN1n, and discharge the node N3 in accordance with the activation of the signal (the output signal Gₖ₊₂ of the second next stage) of the first reverse direction input terminal IN1r.

As a result, the unit shift register SRₖ of FIG. 13 can perform the forward-direction shifting operation in the same manner as the operation of the circuit of FIG. 12. Since the transistor Q3n is operated in the non-saturated region to charge the node N1, the potential of the node N1 is higher by Vth as compared with the circuit of FIG. 11, so that the on-resistance of the transistor Q1 can be reduced. Thus, the rising speed and the falling speed of the output signal Gₖ is increased.

Moreover, since the pull-down drive circuit 23 has the transistors Q18, Q19 similarly to the circuit of FIG. 11, the transistors Q5, Q5D, Q12n are turned OFF at a time point when the transistors Q3n, Q3D, Q11n start charging the nodes N1, N3, N4n, respectively. Thus, the nodes N1, N3, N4n can be charged at a high speed. This contributes to an increase in the speed of the operation of the unit shift register SRₖ.

At a time of the reverse-direction shift, the first voltage signal Vn is set at the L level (VSS), and the second voltage signal Vr is set at the H level (VDD) (second operation mode). In this case, the second voltage signal Vr functions as activation-level power, and the reverse direction pull-up drive circuit 22r is in the activated state (operable state). Since the drains (second voltage signal terminal T2) of the transistors Q3r, Q11r are fixed at the H level (VDD), the reverse direction pull-up drive circuit 22r and the transistor Q5 form a circuit equivalent to the pull-up drive circuit 22 of FIG. 12 (the transistor Q13r (MOS capacitance element) functions similarly to the capacitance element C2 when the node N4r is at the H level).

On the other hand, no activation-level power is supplied to the forward direction pull-up drive circuit 22n, and the forward direction pull-up drive circuit 22n is in the resting state. In this case, no electric charge is supplied to the node N1 through the transistor Q3n. The transistor Q11n cannot charge the node N4n, and no channel is formed in the transistor Q13n (MOS capacitance element), so that the node N4n cannot be boosted. Therefore, the node N4n is kept at the L level, and the transistor Q3n kept in the OFF state.

The transistors Q3D, Q4D (charge/discharge circuit) of the pull-down drive circuit 23 is operated so as to charge the node N3 in accordance with the activation of the signal (the output signal Gₖ₊₂ of the second next stage) of the first reverse direction input terminal IN1r, and discharge the node N3 in accordance with the activation of the signal (the output signal Gₖ₋₂ of the second preceding stage) of the first forward direction input terminal IN1n.

As a result, the unit shift register SRₖ of FIG. 13 can perform the reverse-direction shifting operation in the same manner as the operation of the circuit of FIG. 12. Since the transistor Q3r is operated in the non-saturated region to charge the node N1, the potential of the node N1 is higher by Vth as compared with the circuit of FIG. 11, so that the on-resistance of the transistor Q1 can be reduced. Thus, the rising speed and the falling speed of the output signal Gₖ is increased.

Moreover, since the pull-down drive circuit 23 has the transistors Q18, Q19 similarly to the circuit of FIG. 11, the transistors Q5, Q5D, Q12r are turned OFF at a time point when the transistors Q3r, Q4D, Q11r start charging the nodes N1, N3, N4r, respectively. Thus, the nodes N1, N3, N4r can be charged at a high speed. This contributes to an increase in the speed of the operation of the unit shift register SRₖ.

The output signal Gₖ₋₁ of the immediately preceding stage may be inputted to the second input terminal IN2n, and the next-stage output signal Gₖ₊₁ may be inputted to the second reverse direction input terminal IN2r. In such a case, normal capacitance elements may be used instead of the transistors Q13n, Q13r (MOS capacitance element).

In a case where a clock signal is inputted to each of the second forward direction input terminal IN2n and the second reverse direction input terminal IN2r as described in the example above, there is a concern that when normal capacitance elements are used, they may be boosted to cause an erroneous operation during a period requiring no boosting of the nodes N4n, N4r. Therefore, it is desirable to adopt a MOS capacitance element which selectively functions as a capacitance element only in a necessary period.

While the invention has been shown and described in detail, the foregoing description is in all aspects illustrative and not restrictive. It is therefore understood that numerous modifications and variations can be devised without departing from the scope of the invention.

What is claimed is:

1. A shift register circuit comprising:
an input terminal, an output terminal, a reset terminal, and a clock terminal;
a first transistor which supplies a clock signal inputted to said clock terminal, to said output terminal;
a second transistor which discharges a first node to which a control electrode of said first transistor is connected;
an inverter whose output end is a second node to which a control electrode of said second transistor is connected;
a first charge circuit which charges said first node in accordance with activation of an input signal inputted to said input terminal;
a first discharge circuit which discharges said first node in accordance with activation of a reset signal inputted to said reset terminal;
a second charge circuit which charges a third node in accordance with activation of said input signal, said third node being an input end of said inverter; and
a second discharge circuit which discharges said third node in accordance with activation of said reset signal.

2. The shift register circuit according to claim 1, wherein
said first charge circuit is a third transistor having a control electrode connected to said input terminal,
said first discharge circuit is a fourth transistor having a control electrode connected to said reset terminal,
said second charge circuit is a fifth transistor having a control electrode connected to said input terminal,
said second discharge circuit is a sixth transistor having a control electrode connected to said reset terminal.

3. The shift register circuit according to claim 1, further comprising a seventh transistor having a control electrode connected to said second node, said seventh transistor discharging said third node.

4. The shift register circuit according to claim 3, wherein
said seventh transistor is connected between said third node and said input terminal.

5. The shift register circuit according to claim 1, further comprising a pull-down transistor which discharges said output terminal.

6. The shift register circuit according to claim 5, wherein
a control electrode of said pull-down transistor is connected to said second node.

7. The shift register circuit according to claim 1, further comprising a capacitance element connected between said first node and said output terminal.

8. A shift register circuit comprising:
a first input terminal, a second input terminal, an output terminal, and a clock terminal;
a first transistor which supplies a clock signal inputted to said clock terminal, to said output terminal;
a second transistor which discharges a first node to which a control electrode of said first transistor is connected;
an inverter whose output end is a second node to which a control electrode of said second transistor is connected;
a first charge/discharge circuit which charges and discharges said first node based on a first input signal inputted said first input terminal and a second input signal inputted to said second input terminal; and
a second charge/discharge circuit which charges and discharges a third node based on said first input signal and said second input signal, said third node being an input end of said inverter;
wherein
said first charge/discharge circuit is operable to switch between a first operation mode in which said first node is charged in accordance with activation of said first input signal and discharged in accordance with activation of said second input signal, and a second operation mode in which said first node is charged in accordance with activation of said second input signal and discharged in accordance with activation of said first input signal,
in said first operation mode, said second charge/discharge circuit is operated so as to charge said third node in accordance with activation of said first input signal, and discharge said third node in accordance with activation of said second input signal,
in said second operation mode, said second charge/discharge circuit is operated so as to charge said third node in accordance with activation of said second input signal, and discharge said third node in accordance with activation of said first input signal.

9. The shift register circuit according to claim 8, further comprising first and second voltage signal terminals to which first and second voltage signals complementary to each other are respectively supplied for switching between said first and second operation modes,
wherein
said first charge/discharge circuit includes:
a third transistor having a control electrode connected to said first input terminal, said third transistor being connected between said first voltage signal terminal and said first node; and
a fourth transistor having a control electrode connected to said second input terminal, said fourth transistor being connected between said second voltage signal terminal and said first node,
said second charge/discharge circuit includes:
a fifth transistor having a control electrode connected to said first input terminal, said fifth transistor being connected between said first voltage signal terminal and said third node; and
a sixth transistor having a control electrode connected to said second input terminal, said sixth transistor being connected between said second voltage signal terminal and said third node.

10. The shift register circuit according to claim 9, comprising:
a seventh transistor having a control electrode connected to said first input terminal, said seventh transistor being connected between said second voltage signal terminal and said second node; and
an eighth transistor having a control electrode connected to said second input terminal, said eighth transistor being connected between said first voltage signal terminal and said second node.

11. The shift register circuit according to claim 8, further comprising a ninth transistor having a control electrode connected to said second node, said ninth transistor discharging said third node.

12. The shift register circuit according to claim 8, further comprising a pull-down transistor which discharges said output terminal.

13. The shift register circuit according to claim 12, wherein
a control electrode of said pull-down transistor is connected to said second node.

14. The shift register circuit according to claim 8, further comprising a capacitance element connected between said first node and said output terminal.

15. A shift register circuit comprising:
a first input terminal, a second input terminal, an output terminal, a reset terminal, and a clock terminal;
a first transistor which supplies a clock signal inputted to said clock terminal, to said output terminal;
a second transistor which discharges a first node to which a control electrode of said first transistor is connected;
an inverter whose output end is a second node to which a control electrode of said second transistor is connected;
a third transistor which charges said first node;
a first charge circuit which charges a third node having a control electrode of said third transistor connected thereto, in accordance with activation of a first input signal inputted to said first input terminal;
a boost element which boosts said third node in accordance with activation of a second input signal inputted to said second input terminal;
a first discharge circuit which discharges said third node in accordance with activation of a reset signal inputted to said reset terminal;
a second charge circuit which charges a fourth node in accordance with activation of said first input signal, said fourth node being an input end of said inverter; and
a second discharge circuit which discharges said fourth node in accordance with activation of said reset signal.

16. The shift register circuit according to claim 15, further comprising a fourth transistor having a control electrode connected to said second node, said fourth transistor discharging said fourth node.

17. The shift register circuit according to claim 15 further comprising a pull-down transistor which discharges said output terminal.

18. The shift register circuit according to claim 17, wherein
a control electrode of said pull-down transistor is connected to said second node.

19. The shift register circuit according to claim 15, further comprising a capacitance element which is connected between said first node and said output terminal.

20. A shift register circuit comprising:
first to fourth input terminals, an output terminal, a reset terminal, and a clock terminal;
a first transistor which supplies a clock signal inputted to said clock terminal, to said output terminal;
a second transistor which discharges a first node to which a control electrode of said first transistor is connected;
an inverter whose output end is a second node to which a control electrode of said second transistor is connected;
a first charge circuit which charges said first node in accordance with activation of a first input signal inputted to said first input terminal;
a second charge circuit which charges said first node in accordance with activation of a second input signal inputted to said second input terminal; and
a charge/discharge circuit which charges and discharges a third node based on said first input signal and said second input signal, said third node being an input end of said inverter,
wherein
said first charge circuit includes:
a third transistor which charges said first node;
a first charge element which charges a fourth node having a control electrode of said third transistor connected thereto, in accordance with activation of said first input signal; and
a first boost element which boosts said fourth node in accordance with activation of a third input signal inputted to said third input terminal,
said second charge circuit includes:
a fourth transistor which charges said first node;
a second charge element which charges a fifth node having a control electrode of said fourth transistor connected thereto, in accordance with activation of said second input signal; and
a second boost element which boosts said fifth node in accordance with activation of a fourth input signal inputted to said fourth input terminal,
said first charge circuit and said second charge circuit are operable to switch between a first operation mode in which said first charge circuit is operated and said second charge circuit is in a resting state, and a second operation mode in which said second charge circuit is operated and said first charge circuit is in the resting state,
in said first operation mode, said charge/discharge circuit is operated so as to charge said third node in accordance with activation of said first input signal, and discharge said third node in accordance with activation of said second input signal,
in said second operation mode, said charge/discharge circuit is operated so as to charge said third node in accordance with activation of said second input signal, and discharge said third node in accordance with activation of said first input signal.

21. The shift register circuit according to claim 20, further comprising first and second voltage signal terminals to which first and second voltage signals complementary to each other are respectively supplied for switching between said first and second operation modes,
wherein
in said first charge circuit:
said third transistor is connected between said first voltage signal terminal and said first node;
said first charge element is a fifth transistor having a control electrode connected to said first input terminal, said fifth transistor being connected between said first voltage signal terminal and said fourth node; and
said first boost element is a first capacitance element connected between said third input terminal and said fourth node,
in said second charge circuit:
said fourth transistor is connected between said second voltage signal terminal and said first node;
said second charge element is a sixth transistor having a control electrode connected to said fourth input terminal, said sixth transistor being connected between said second voltage signal terminal and said fifth node; and
said second boost element is a second capacitance element connected between said fourth input terminal and said fourth node.

22. The shift register circuit according to claim 21, wherein
said charge/discharge circuit includes:
a seventh transistor having a control electrode connected to said first input terminal, said seventh transistor being connected between said first voltage signal terminal and said third node; and
an eighth transistor having a control electrode connected to said second input terminal, said eighth transistor being connected between said second voltage signal terminal and said third node.

23. The shift register circuit according to claim 22, further comprising:
a ninth transistor having a control electrode connected to said first input terminal, said ninth transistor being connected between said second voltage signal terminal and said second node; and
a tenth transistor having a control electrode connected to said second input terminal, said tenth transistor being connected between said first voltage signal terminal and said second node.

24. The shift register circuit according to claim 20, further comprising an eleventh transistor having a control electrode connected to said second node, said eleventh transistor discharging said third node.

25. The shift register circuit according to claim 20, further comprising a pull-down transistor which discharges said output terminal.

26. The shift register circuit according to claim 25, wherein
a control electrode of said pull-down transistor is connected to said second node.

27. The shift register circuit according to claim 20, further comprising a capacitance element connected between said first node and said output terminal.
